(19) United States
(12) Patent Application Publication
(10) Pub. No.: US 2011/0215478 A1
(43) Pub. Date: Sep. 8, 2011

(54) SEMICONDUCTOR ELEMENT-EMBEDDED WIRING SUBSTRATE

(75) Inventors: Shintaro YAMAMICHI, Minato-ku (JP); Hideya MURAI, Minato-ku (JP); Kentaro MORI, Minato-ku (JP); Katsumi KIKUCHI, Minato-ku (JP); Yoshiki NAKASHIMA, Minato-ku (JP); Masaya KAWANO, Kawasaki (JP); Masahiro KOMURO, Kawasaki (JP)

(73) Assignees: NEC CORPORATION, Tokyo (JP); RENESAS ELECTRONICS CORPORATION, Kawasaki-shi (JP)

(21) Appl. No.: 13/040,021

(22) Filed: Mar. 3, 2011

(30) Foreign Application Priority Data
Mar. 4, 2010 (JP) 2010-047862

(51) Int. Cl. H01L 23/522

(52) U.S. Cl. 257/773; 257/E23.142

(57) ABSTRACT

In a wiring substrate containing a semiconductor element, the wiring substrate includes a supporting substrate; a semiconductor element provided on the supporting substrate; a peripheral insulating layer covering at least an outer circumferential side surface of the semiconductor element; and upper surface-side wiring provided on the upper surface side of the wiring substrate. The semiconductor element includes a semiconductor substrate; a first wiring-structure layer including first wiring and a first insulating layer alternately formed on the semiconductor substrate; and a second wiring-structure layer including second wiring and a second insulating layer alternately formed on the first wiring-structure layer. The upper surface-side wiring includes fan-out wiring led out from immediately above the semiconductor element to a peripheral region external to an outer edge of the semiconductor element. The fan-out wiring is electrically connected to the first wiring through the second wiring. The second wiring is thicker than the first wiring but thinner than the upper surface-side wiring. The second insulating layer is formed of a resin material and is thicker than the first insulating layer.

This application is based upon and claims the benefit of priority from Japanese patent application No. 2010-047862, filed on Mar. 4, 2010, the disclosure of which is incorporated herein in its entirety by reference.

### BACKGROUND OF THE INVENTION

1. Field of the Invention

The present invention relates to a wiring substrate in which a semiconductor element is embedded.

2. Description of the Related Art

As the result of reductions in the size and weight of electronic apparatus, high-density mounting technology in semiconductor packages has progressed along with the miniaturization and the high integration of semiconductor elements.

In the packaging of a semiconductor element, such as an IC chip, a connection between a wiring substrate and a semiconductor element within a package is made by means of wire bonding connection using a gold wire or the like or flip-chip connection using solder balls or the like.

Wire bonding connection has the advantage of being able to perform packaging at low costs as long as the semiconductor element has only a small number of connecting pads. A wire diameter needs to be made smaller, however, due to an increase in the number of connecting pads and the narrowing of pitches. Accordingly, wire bonding connection is problematic in that a yield degrades due to assembly failure, such as wire breakage. In addition, wire bonding connection requires certain amounts of distance for connection paths between terminals of the semiconductor element and terminals of the wiring substrate. Thus, wire bonding connection is also problematic in that high-speed transmission characteristics are liable to degradation.

Flip-chip connection allows for high-speed signal transmission since a connection path between the semiconductor element and the wiring substrate is shorter, compared with that in wire bonding connection. In addition, terminals can be provided not only in the periphery of a circuit-formed surface of the semiconductor element but also across the entire area thereof. Consequently, it is possible to increase the number of connecting terminals. As the result of an increase in the number of connecting pads of the semiconductor element and the narrowing of pitches, however, connection strength is reduced due to with a decrease in the size of solder bumps. Accordingly, flip-chip connection is problematic in that connection failure, such as cracks, is liable to occur.

In recent years, packaging technology for building a semiconductor element in a wiring substrate, i.e., so-called semiconductor element-embedding technology has been proposed as a high-density mounting technique for facilitating further densification and functional upgrading of semiconductor devices. This technology is advantageous in the thinning and cost reduction of packages, compatibility with high frequencies, low-stress connection, improvement in electromigration properties, and the like.

For example, JP2001-15650A discloses a ball grid array package provided with an IC chip fixed onto a metal heat-dissipating plate and buried using an insulating layer; a wiring conductor to be directly connected to a mounting pad of this IC chip; a BGA mounting pad formed externally and electrically connected to this wiring conductor; and a BGA solder bump bonded to this BGA mounting pad.

In addition, JP2004-95836A discloses a semiconductor device provided with a semiconductor structure (CSP: chip size package) including a semiconductor chip, rewiring on this semiconductor chip, a sealing film covering this rewiring, and a columnar electrode on this rewiring; a frame-shaped embedding material provided lateral to this semiconductor structure; a sealing film provided between this semiconductor structure and this frame-shaped embedding material; an insulating film covering this semiconductor structure; and upper-layer rewiring provided on this insulating film and connected to the columnar electrode, wherein the semiconductor structure and the frame-shaped embedding material are provided on a base plate.

On the other hand, JP2006-32600A discloses, as a semiconductor chip to be mounted on a mounting board, a semiconductor device including a fine wiring structure in which a first wiring layer and a first insulating layer are alternately laminated on a semiconductor substrate; a first enormous wiring structure in which a second wiring layer and a second insulating layer are alternately laminated on this fine wiring structure; and a second enormous wiring structure in which a third wiring layer and a third insulating layer are alternately laminated on this first enormous wiring structure, wherein the second and third insulating layers are thicker than the first insulating layer, the elastic modulus of the third insulating layer at 25° C. is less than the elastic modulus of the second insulating layer at 25° C., and the thicknesses of the second and third wiring layers are twice or more the thickness of the first wiring layer. The patent document describes that such a semiconductor device as mentioned above can reduce stress arising after the semiconductor device is mounted on the mounting board.

### SUMMARY

However, the above-described semiconductor element-embedding technology has such a problem as described below.

In the technique described in JP2001-15650A, the conductive wire to be connected to the IC chip fixed onto the metal heat-dissipating plate is formed on a pad of the IC chip directly (or through a conductive part filled in an opening of the insulating layer on the pad) by a plating method. Thereafter, a multilayer structure is formed by a regular buildup construction method. In such a structure as described above, there is a significant difference in design rule, such as pitches, between the wiring structure on the IC chip and the fine wiring structure within the IC chip. Accordingly, it is difficult to lead out adequate signal lines from the IC chip. Hence, it is conceivable to provide a plurality of wiring layers within the IC chip, so that the IC chip has a pitch suited for the multilayer wiring structure on the upper-layer side. However, this method involves an increase in the number of laminated wiring layers within the IC chip, thus raising the manufacturing cost of the IC chip.

In the technique described in JP2004-95836A, rewiring to be connected to pads of the semiconductor chip is provided, so that the arrangement pitch of electrodes for external connection can be increased. However, wiring lines are laminated at the same pitch and thickness from the rewiring layer on the lowermost layer side to be connected to the semiconductor chip up to the rewiring layer on the uppermost-layer side to be connected to external terminals. Such a multilayer wiring structure as described above causes a large difference in design rule with respect to the fine wiring structure within the semiconductor chip. Accordingly, complying with the rules of a wiring board to be used for mounting fails to make a wiring pitch and the like compatible with the pitches of connecting parts and the like of the semiconductor chip. Thus, it is difficult to lead out adequate signal lines from the semiconductor chip. In addition, although complying with the rules of the semiconductor chip makes it easy to make the wiring pitch compatible, wiring resistance increases. This results in not only failure to obtain desired electrical characteristics but also such a problem as wiring disconnection due to stress. Furthermore, the respective layers of this multilayer wiring structure are thick, and therefore, multilayering for the sake of rewiring causes difficulty in thinning the device as a whole.

In addition, in a wiring substrate containing a semiconductor element, such as a semiconductor chip, constituent materials of the semiconductor element and a resin material used for the wiring substrate largely differ in thermal expansion coefficient from each other. Consequently, the wiring substrate is problematic in that a large amount of stress is applied to an electrically-connected part between the semiconductor element and the wiring substrate, and therefore, this connected part is liable to break down. This problem becomes more prominent if the wiring substrate contains a semiconductor element including a low-dielectric constant film (low-k film) poor in mechanical characteristics and having a relative permittivity of 3 or lower.

An exemplary object of the invention is to provide a thin, high-reliability wiring substrate containing a high-density semiconductor element.

According to an aspect of the invention, there is provided a wiring substrate containing a semiconductor element, the wiring substrate including:
a supporting substrate;
a semiconductor element provided on the supporting substrate;
a peripheral insulating layer provided on the supporting substrate and covering at least an outer circumferential side surface of the semiconductor element; and
upper surface-side wiring provided on the upper surface side of the wiring substrate, the semiconductor element including:
a semiconductor substrate;
a first wiring-structure layer including first wiring and a first insulating layer alternately formed on the semiconductor substrate; and
a second wiring-structure layer including second wiring and a second insulating layer alternately formed on the first wiring-structure layer,

wherein the upper surface-side wiring includes fan-out wiring led out from immediately above the semiconductor element to a peripheral region external to an outer edge of the semiconductor element, the fan-out wiring being electrically connected to the first wiring through the second wiring;

the thickness of the second wiring is greater than the thickness of the first wiring but less than the thickness of the upper surface-side wiring; and

the second insulating layer is formed of a resin material and greater in thickness than the first insulating layer.

### BRIEF DESCRIPTION OF THE DRAWINGS

FIG. 1 is a cross-sectional view illustrating a wiring substrate according to a first exemplary embodiment of the present invention;

FIG. 2 is a cross-sectional view illustrating a semiconductor element built in the wiring substrate of the first exemplary embodiment;

FIG. 3 is a cross-sectional view illustrating a modified example of the wiring substrate according to the first exemplary embodiment of the present invention;

FIG. 4 is a cross-sectional view illustrating a wiring substrate according to a second exemplary embodiment of the present invention;

FIG. 5 is a cross-sectional view illustrating a modified example of the wiring substrate according to the second exemplary embodiment of the present invention;

FIG. 6 is a cross-sectional view illustrating a wiring substrate according to a third exemplary embodiment of the present invention; and

FIG. 7 is a cross-sectional view illustrating a wiring substrate according to a fourth exemplary embodiment of the present invention.

### DETAILED DESCRIPTION OF THE PREFERRED EMBODIMENTS

A semiconductor element-embedded wiring substrate according to an exemplary embodiment of the present invention includes a supporting substrate; a semiconductor element provided on this supporting substrate; a peripheral insulating layer provided on this supporting substrate and covering at least an outer circumferential side surface of the semiconductor element; and upper surface-side wiring provided on the upper surface side of this wiring substrate. The semiconductor element built in this wiring substrate includes a semiconductor substrate; a first wiring-structure layer that includes first wiring and a first insulating layer alternately formed on this semiconductor substrate; and a second wiring-structure layer that includes second wiring and a second insulating layer alternately formed on this first wiring-structure layer. The upper surface-side wiring includes fan-out wiring led out from immediately above the built-in semiconductor element to a peripheral region (an upper surface of the peripheral insulating layer) external to an outer edge of the semiconductor element. This fan-out wiring is electrically connected to the first wiring through the second wiring.

The thickness of the second wiring is greater than the thickness of the first wiring but is less than the thickness of the upper surface-side wiring.

The second insulating layer is composed of a resin material and the thickness thereof is greater than the thickness of the first insulating layer. The second insulating layer is composed of a material different from that of the first insulating layer. As the material of the first insulating layer, a material selected with priority placed on electrical characteristics and high processing accuracy is preferably used. As the material of the second insulating layer, a high-toughness resin material selected with importance placed on reliability is preferably used. Consequently, impact resistance can be enhanced even if the semiconductor element is made thinner. In addition, with such a second wiring-structure layer that includes the second insulating layer composed of a resin material, it is possible to attain a stress relief effect. The second wiring-structure layer preferably includes, as the second insulating layer, an insulating layer having an elastic modulus lower than the elastic modulus of the first insulating layer. In addition, the second insulating layer preferably does not include a filler.

The first wiring-structure layer preferably includes, as the first insulating layer, an insulating layer formed of an inorganic insulating material from the viewpoint of processing accuracy and the like. In addition, the first wiring-structure layer may include, as the first insulating layer, an insulating layer formed of a low-k material from the viewpoint of electrical characteristics and the like. The first wiring-structure layer may include both the insulating layer formed of the inorganic insulating material and the insulating layer formed of the low-k material. The first wiring-structure layer may include an insulating layer formed of an organic material.

The thickness of the second wiring is greater than the thickness of the first wiring, and the thickness of the second insulating layer is greater than the thickness of the first insulating layer. This second wiring preferably has a thickness twice or more the thickness of the first wiring and, more preferably, three times or more the thickness thereof. This second insulating layer preferably has a thickness twice or more the thickness of the first insulating layer and, more preferably, three times or more the thickness thereof.

The second wiring is formed by a design rule different from the design rule of the first wiring and the design rule of the upper surface-side wiring. The minimum wiring width and the minimum wiring pitch of the second wiring are preferably greater than the minimum wiring width and the minimum wiring pitch of the first wiring, respectively, but less than the minimum wiring width and the minimum wiring pitch of the upper surface-side wiring.

The entire lower surface of the second wiring-structure layer may be provided on an upper surface of the first wiring-structure layer. The outer circumferential side surface of the second wiring-structure layer, along with the outer circumferential side surfaces of the first wiring-structure layer and the semiconductor substrate, can compose an outer circumferential side surface for the semiconductor element.

The first wiring-structure layer includes, on the upper surface side thereof, a first connecting part connected to the second wiring. The second wiring-structure layer includes, on the upper surface side thereof, a second connecting part conductive to the first connecting part and connected to the fan-out wiring. This second connecting part is preferably repositioned in a direction farther from a position of the first connecting part toward an outer edge side of the semiconductor element.

The wiring substrate of the present exemplary embodiment can include a protective insulating film that covers the abovementioned upper surface-side wiring. This protective insulating film can include an opening such that the wiring substrate is provided with an external terminal composed of an exposed portion of the upper surface-side wiring within this opening or an external terminal composed of a conductive part provided in this opening.

The wiring substrate of the present exemplary embodiment can include a third wiring-structure layer that includes third wiring and a third insulating layer alternately formed on this wiring substrate. This third wiring-structure layer can include the fan-out wiring as the third wiring on at least the lowermost layer side. This fan-out wiring can be electrically connected to an upper layer-side wiring provided in the third wiring-structure layer as the third wiring.

This third insulating layer can be formed of a resin material different from the material of the second insulating layer. This third insulating layer can contain a filler, whereas the second insulating layer preferably does not contain a filler.

The thickness of the third wiring is preferably greater than the thickness of the second wiring. In addition, the thickness of the third insulating layer is preferably greater than the thickness of the second insulating layer. This third wiring preferably has a thickness twice or more the thickness of the second wiring. This third insulating layer preferably has a thickness twice or more the thickness of the second insulating layer.

If the wiring substrate of the present exemplary embodiment includes the above-mentioned third wiring-structure layer, the wiring substrate may include an insulating layer on the uppermost layer side. The insulating layer can include an opening such that the wiring substrate is provided with an external terminal composed of an exposed portion of the third wiring in this opening or an external terminal composed of a conductive part provided within this opening.

The abovementioned peripheral insulating layer can be composed of a resin material. This resin material may contain a filler or a reinforcing material made of woven or nonwoven cloth.

In the wiring substrate of the present exemplary embodiment, it is possible for the abovementioned peripheral insulating layer to cover the outer circumferential side surface of a mounted semiconductor element without covering the upper surface thereof. Thus, the fan-out wiring can be laid out from an upper-surface terminal of this semiconductor element onto this peripheral insulating layer. Alternatively, it is possible for this peripheral insulating layer to cover the upper surface and the outer circumferential side surface of the mounted semiconductor element. Thus, the fan-out wiring can be laid out on this peripheral insulating layer, from a region immediately above the semiconductor element to a region external to an outer edge of the semiconductor element.

The wiring substrate of the present exemplary embodiment can include an element-side via that penetrates the peripheral insulating layer. This element-side via can connect the third wiring and the supporting substrate.

A semiconductor element to be mounted can include, on the lower surface side of the semiconductor substrate thereof, a fourth wiring-structure layer that includes a fourth insulating layer and fourth wiring. The fourth insulating layer and the fourth wiring can be alternately formed to form a multilayer structure. This semiconductor element can include an intra-element via that penetrates the semiconductor substrate. The first wiring and the fourth wiring can be electrically connected through this intra-element via.

The abovementioned semiconductor element can include a reinforcing via penetrating the semiconductor substrate.

In the description of the present invention, comparison of wiring thicknesses and insulating layer thicknesses between an upper layer-side wiring-structure layer and a lower layer-side wiring-structure layer respectively is defined as comparison of the minimum thickness of wirings and insulating layers of the upper layer-side wiring-structure layer with the maximum thickness of wirings and insulating layers of the lower layer-side wiring-structure layer. For example, the expression “the thickness of the second wiring is greater than the thickness of the first wiring” means that the minimum thickness of the second wiring is greater than the maximum thickness of the first wiring. Likewise, the expression “the second wiring has a thickness twice or more the thickness of the first wiring” means that the minimum thickness of the second wiring is twice or more the maximum thickness of the first wiring.

In the present exemplary embodiment, the thickness of the first wiring can be set to 0.08 μm or greater but not greater than 1.6 μm, and is preferably 0.1 μm or greater but not greater than 1.2 μm. In that case, the thickness of the second wiring is preferably set to 3 μm or greater but not greater than 12 μm, and more preferably 5 μm or greater but not greater than 10 μm. The thickness of the third wiring is preferably set greater than the thickness of the second wiring thus set.

The thickness of an insulating layer can be set as appropriate, according to the thickness of wiring. The thickness of the first insulating layer can be set to 0.09 μm or greater but not greater than 3.0 μm, and is preferably set to 0.1 μm or greater but not greater than 2.0 μm. The thickness of the second insulating layer can be set to, for example, 3 μm or greater, and is preferably set to 4 μm or greater but not greater than 30 μm, more preferably 7 μm or greater but not greater than 20 μm. The thickness of the third insulating layer is preferably set greater than the thickness of the second insulating layer thus set.

In the description of the present invention, the thickness of an insulating layer provided alternately with wiring in each wiring-structure layer is defined as a length along a thickness direction (direction perpendicular to a plane of the substrate) from the upper surface of an insulating layer in contact with the lower surface of a lower layer-side wiring up to the upper surface of an insulating layer in contact with the lower surface of an upper layer-side wiring.

According to the present exemplary embodiment, it is possible to consolidate power supply wiring and grounding wiring, respectively, in the second wiring-structure layer provided on the fine, first wiring-structure layer of the semiconductor element. As a result, the number of terminals can be decreased. If the number of terminals can be decreased, then the size and pitch of terminals can be increased. Consequently, it is possible to enhance mountability and connection reliability. In addition, with fan-out wiring led out from the semiconductor element to a peripheral region, it is possible to form wiring structures and terminals at pitches fully expanded with respect to pitches within the semiconductor element. Since the number of terminals can be decreased and wiring pitches and terminal pitches can be expanded as described above, it is possible to build in a higher-density semiconductor element and enhance connection reliability. In addition, since a greater number of signal lines can be led out, it is possible to build in a more highly-functional semiconductor element.

According to the present exemplary embodiment, the presence of the second wiring-structure layer between the upper surface-side wiring (or the third wiring-structure layer) and the first wiring-structure layer allows stress arising mainly due to thermal deformation to be relieved, thereby suppressing connection failure.

Since there is a large difference in the rate of thermal expansion between an insulating material (inorganic material or “low-k material) of the semiconductor element and an insulating material (resin material) constituting the wiring substrate (or members provided on this wiring substrate) for accommodating this semiconductor element, stress arises (in particular, lateral stress along a substrate plane) in a connecting part between the semiconductor element and the wiring substrate (for example, a connecting part between a via and a terminal pad) at the time of manufacture or use. Thus, there is the problem that this connecting part is liable to break down. This problem is ascribable to the fact that mechanical characteristics of insulating materials of the semiconductor element are poor, and becomes more prominent when a low-dielectric constant material (low-k material) is used. The second insulating layer of the second wiring-structure layer in the present exemplary embodiment is formed of a resin material superior in mechanical characteristics, in particular, rupture strength and the percentage of elongation at break which are mechanical strengths, to the material of the first insulating layer. Consequently, stress can be relieved by this second wiring-structure layer. From the viewpoint of attaining an adequate stress relief effect, the second wiring-structure layer preferably includes, as the second insulating layer, an insulating layer having an elastic modulus lower than the elastic modulus of the first insulating layer. If a third wiring-structure layer is provided, the second wiring-structure layer preferably includes, as the second insulating layer, an insulating layer having an elastic modulus greater than the elastic modulus of the third insulating layer. Comparison among the elastic moduli of these insulating layers is defined as comparison at 25° C. For the materials of the second and third insulating layer, it is possible to use materials whose elastic modulus at 25° C. is, for example, 0.15 to 8 GPa. For the material of the first insulating layer, it is possible to use a material whose elastic modulus at 25° C. is, for example, 4 GPa or greater. As the low-k material, it is possible to suitably use a material whose elastic modulus at 25° C. is 4 to 10 GPa.

In the description of the present invention, the film strength and the percentage of elongation at break of insulating layers correspond to the measured values of an insulating material tensile test compliant to JIS K 7161 (tensile characteristics test). The elastic moduli correspond to values calculated from strength at a strain of 0.1% based on the results of this tensile test. The rates of thermal expansion correspond to measured values based on a TMA method compliant to JIS C 6481.

The second wiring is preferably formed by a design rule intermediate in size between the design rule of the fine first wiring and the design rule of the large-scale upper surface-side wiring (or third wiring). With the second wiring-structure layer that includes such second wiring, it is possible to moderately relieve stress concentration at connecting parts due to a drastic size difference in cases where no second wiring-structure layer is provided. In addition, the second wiring-structure layer has a combination of wiring thicknesses and insulation thicknesses capable of fully coping with stress. Furthermore, it is possible to secure a contact area of a via part capable of fully coping with stress concentrating on a connecting part. Consequently, there can be obtained connection strength by which a favorable connection state can be maintained even in case of stress generation. In addition, as described above, the second wiring-structure layer allows adequate signal lines to be led out from the first wiring-structure layer.

The minimum design rule of wiring (L/S) in the first wiring-structure layer, the second wiring-structure layer, and the third wiring-structure layer (or the upper surface-side wiring) is preferably set as described below (L denotes a wiring width and S denotes a wiring pitch):

The minimum design rule of wiring of the first wiring-structure layer is preferably L/S=0.01 μm/0.01 μm. That is, the first wiring is preferably 0.01 μm or greater in the minimum wiring width and 0.01 μm or wider in the minimum wiring pitch.

The minimum design rule of wiring of the second wiring-structure layer is preferably L/S=2 μm/2 μm. That is, the second wiring is preferably 2 μm or greater in the minimum wiring width and 2 μm or wider in the minimum wiring pitch.

The minimum design rule of wiring of the third wiring-structure layer (or the upper surface-side wiring) is preferably L/S=5 μm/5 μm. That is, the third wiring (or the upper surface-side wiring) is preferably 5 μm or greater in the minimum wiring width and 5 μm or wider in the minimum wiring pitch.

From the viewpoint of yield stabilization, wiring-structure layers are preferably set to the below-described design rules:

The minimum design rule of wiring of the first wiring-structure layer is preferably L/S=0.02 μm/0.02 μm. That is, the first wiring is preferably 0.02 μm or greater in the minimum wiring width and 0.02 μm or wider in the minimum wiring pitch.

The minimum design rule of wiring of the second wiring-structure layer is preferably L/S=5 μm/5 μm. That is, the second wiring is 5 μm or greater in the minimum wiring width and 5 μm or wider in the minimum wiring pitch.

The minimum design rule of wiring of the third wiring-structure layer (or the upper surface-side wiring) is preferably L/S=20 μm/20 μm. That is, the third wiring (or the upper surface-side wiring) is preferably 20 μm or greater in the minimum wiring width and 20 μm or wider in the minimum wiring pitch.

As the chip size of the semiconductor element whose planar shape is polygonal (convexly polygonal), such as square or rectangular, the length of a side is preferably 0.2 mm or greater, more preferably 1 mm or greater, from the viewpoint of processing accuracy and the like. From the viewpoint of miniaturization, the side length is preferably 15 mm or less, more preferably 12 mm or less. In this case, the circumferential length of the chip size of the semiconductor element is preferably 0.8 mm or greater, more preferably 4 mm or greater, but is preferably 60 mm or less, more preferably 50 mm or less.

By using an insulating material not containing a filler for the second wiring-structure layer of a semiconductor element to be built in, it is possible to easily form a fine, high-reliability wiring structure compatible with a fine pitch of the first wiring-structure layer. As a result, it is possible to minimize a pitch to be expanded in the first wiring-structure layer. Consequently, it is possible to realize a decrease in the number of layers constituting the first wiring-structure layer. It is also possible to decrease the number of layers in the second wiring-structure layer by improving the rate of containing wiring, and thereby reduce the cost of manufacture.

The third wiring-structure layer can be formed using buildup materials for a regular printed wiring substrate, and therefore, can be manufactured at low costs. In addition, a filler-containing resin material can be used as the insulating material of the third wiring-structure layer. Thus, it is possible to increase heat resistance and mechanical strength. Furthermore, it is possible to reduce a difference in thermal expansion from the semiconductor element, thereby realizing a low degree of warpage. In addition, a resin material relatively low in film forming temperature can be used as the insulating material of the third wiring-structure layer. Consequently, it is possible to maintain process temperature low. As a result, it is possible to reduce warpage of the wiring substrate as a whole and material degradation, thereby enhancing reliability.

Hereinafter, exemplary embodiments of the present invention will be described specifically with reference to the accompanying drawings.

### First Exemplary Embodiment

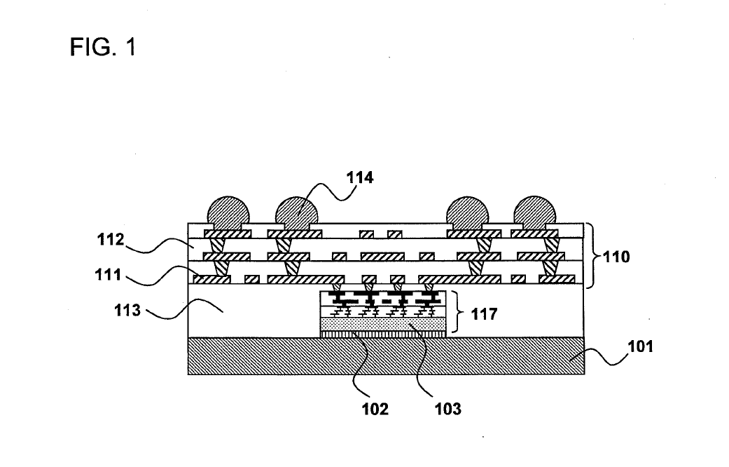

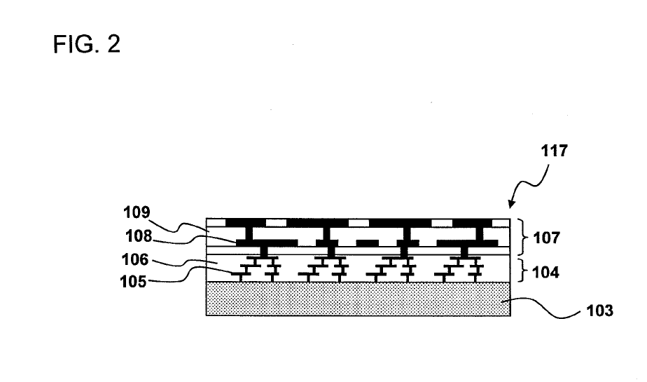

FIG. 1 is a cross-sectional view of a wiring substrate according to a first exemplary embodiment of the present invention, whereas FIG. 2 is a cross-sectional view illustrating a semiconductor element built in this wiring substrate.

In the wiring substrate of the present exemplary embodiment, a semiconductor element 117 illustrated in FIG. 2 is fixed onto a supporting substrate 101 with the intervention of an adhesion layer 102, as illustrated in FIG. 1. A peripheral insulating layer 113 is provided on the supporting substrate 101, so as to cover the lateral periphery (including the lateral periphery of a second wiring-structure layer) and the upper surface of this semiconductor element 117. A third wiring-structure layer 110 is formed on this peripheral insulating layer 113, so as to cover the semiconductor element 117. In this way, a wiring substrate containing a semiconductor element is configured.

The semiconductor substrate 103 of this semiconductor element is ground before being fixed, so as to have a predetermined thickness. The adhesion layer 102 is provided on the ground surface. A function element, such as a MOSFET (not illustrated), and a fine multilayer wiring structure (first wiring-structure layer) 104 electrically connected to this function element are provided on this semiconductor substrate 103. A second wiring-structure layer 107 is provided on this first wiring-structure layer 104. The function element and the first wiring-structure layer can be formed by regular semiconductor manufacturing process technology. The second wiring-structure layer can be formed utilizing later-described wiring technology (wafer-level rewiring technology) known as super-connect.

As illustrated in FIG. 2, the first wiring-structure layer 104 includes first wiring 105 and a first insulating layer 106 provided alternately. Likewise, the second wiring-structure layer 107 includes second wiring 108 and a second insulating layer 109 provided alternately. The second insulating layer 109 is made of an insulating material different from that of the first insulating layer 106. The thickness of the second insulating layer 109 is greater than the thickness of the first insulating layer 106. The thickness of the second wiring 108 is greater than the thickness of the first wiring 105. Note that in the figure, a plurality of insulating layers of the first wiring-structure layer is depicted in an integrated manner.

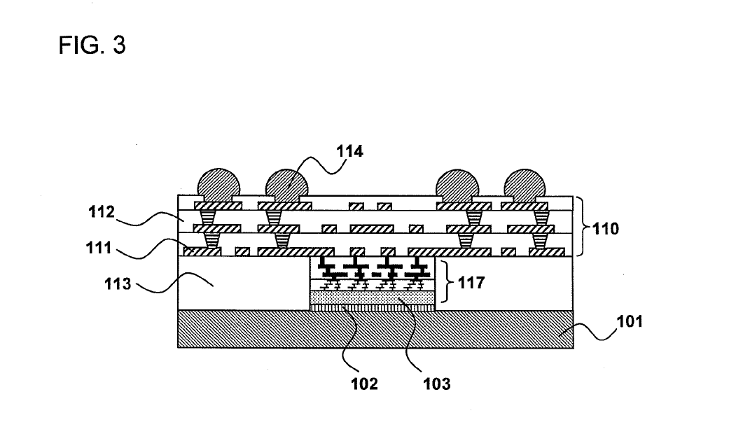

The second wiring-structure layer 107 includes a second wiring 108, a second insulating layer 109, vias, and terminals. The second insulating layer and the second wiring are laminated alternately. Although only one layer of the second wiring is provided in FIG. 2, a plurality of layers of the second wiring may be provided. In this case, the upper layer-side second wiring and the lower layer-side second wiring can be connected to each other by using a via penetrating the second insulating layer between these wiring layers. At a connecting part between the second wiring-structure layer 107 and the first wiring-structure layer 104, the second wiring 108 (or the lowermost layer-side second wiring) is connected to an upper surface-side conductive part of the first wiring-structure layer 104 by using a via penetrating a lowermost layer-side second insulating layer (second insulating layer in contact with a first wiring-structure layer 210), as illustrated in FIG. 2. In substitution for such a structure as described above, the second wiring may be provided on the first wiring-structure layer, so as to be directly connected to the upper surface-side conductive part of the first wiring-structure layer 104. A pad terminal to be connected to the second wiring 108 through a via can be provided on the upper surface of the second wiring-structure layer 107, as illustrated in FIG. 2. In substitution for this pad terminal, a small-diameter terminal may be formed by providing an opening in which the second wiring is exposed in the uppermost layer-side insulating layer and filling a conductive material in this opening, as illustrated in FIG. 3.

The third wiring-structure layer 110 includes third wiring 111 and a third insulating layer 112 provided alternately. The lower layer-side third wiring is electrically connected to the upper layer-side third wiring through a via. Lowermost layer-side third wiring 111 includes fan-out wiring led out from immediately above the semiconductor element to a peripheral region external to an outer edge of the semiconductor element; peripheral wiring extending from this fan-out wiring or connected thereto; and wiring within a region immediately above the semiconductor element. The fan-out wiring is electrically connected to the second wiring 108 of the second wiring-structure layer through a via penetrating an insulating layer (a peripheral insulating layer in the present exemplary embodiment) immediately above the semiconductor element and a terminal on the upper surface of the semiconductor element to which this via is connected. Vias are connected to an extension portion of the fan-out wiring extending to a peripheral region and to the peripheral wiring. The vias are electrically connected to the upper layer-side third wiring. The vias are not limited to those to be connected to the extension portion of the fan-out wiring and the peripheral wiring. Further, vias may be provided within a region immediately above the semiconductor element. Consequently, it is possible to form wiring structures and external terminals at pitches fully expanded with respect to pitches within the semiconductor element. The uppermost layer-side third wiring 111 is covered with the uppermost layer-side third insulating layer (protective insulating layer). A bump is provided in an opening of this third insulating layer as an external terminal 114. In addition to the fan-out wiring formed of the lowermost layer-side third wiring, upper layer-side third wiring may be led out from immediately above the semiconductor element to a peripheral region external thereto.

In substitution for the third wiring-structure layer 110, there may be provided a single layer of lowermost layer-side wiring (upper surface-side wiring) including the fan-out wiring. In addition, a protective insulating film for covering this lowermost layer-side wiring may be provided. Furthermore, an opening in which the wiring is exposed may be provided in this protective insulating film, so as to serve as a connecting terminal portion. Alternatively, a bump may be provided in this opening to form an external terminal.

As the supporting substrate 101, a metal plate made of pure copper, pure aluminum, a copper alloy, an aluminum alloy, or the like, a silicon plate, an organic resin plate, a printed-wiring substrate, or a ceramic plate may be used, for example, though the supporting substrate is not limited to these. From the viewpoint of the productivity of the wiring substrate as well as the heat dissipation properties and manufacturing costs thereof, the supporting substrate 101 is preferably a metal plate, more preferably a copper alloy plate. In one exemplary embodiment of the present exemplary embodiment, a copper alloy plate 30 mm×30 mm in size and 250 μm in thickness is used as the supporting substrate 101. For this supporting substrate 101, a plate of a predetermined size cut out from a larger-size (for example 510 mm×610 mm) plate can be used.

The adhesion layer 102 is not limited in particular, as long as the semiconductor element can be fixed onto the supporting substrate 101 with a desired strength. For example, semi-cured resin referred to as a die attachment film (DAF), epoxy resin, polyimide resin, resin paste such as BCB (benzocyclobutene) or PBO (polybenzoxazole), or silver paste can be used. In an example of the present exemplary embodiment, a DAF consisting primarily of epoxy resin is used.

As the semiconductor substrate 103, a substrate made of, for example, silicon, germanium, gallium arsenic (GaAs), gallium arsenide phosphide, gallium nitride (GaN), silicon carbide (SiC), zinc oxide (ZnO), or any other compound semiconductor (II-VI group compound, III-V group compound, or VI group compound), or diamond can be used, though not limited to these. In an example of the present exemplary embodiment, a silicon substrate is used and, as the semiconductor element 117, an LSI chip is used. The thickness of the semiconductor substrate 103 can be adjusted as appropriate, according to the thickness of a desired wiring substrate. In the example of the present exemplary embodiment, the thickness of the semiconductor substrate 103 is defined as 50 μm and the chip size is defined as 10 mm square.

Although in the present exemplary embodiment illustrated in FIG. 1, one semiconductor element is built in one wiring substrate, a plurality of semiconductor elements may be built in one wiring substrate.

The first wiring-structure layer 104 of the semiconductor element 117 can be formed by regular semiconductor manufacturing process technology.

In the first wiring-structure layer 104, an interlayer insulating film is provided so as to cover a function element, such as a MOSFET, provided on the semiconductor substrate 103. On this interlayer insulating film, there are provided first wiring and an inter-wiring insulating layer for filling spaces between wiring lines. On this first wiring and inter-wiring insulating layer, there is further provided an interlayer insulating film. On this interlayer insulating film, there are provided another first wiring and an inter-wiring insulating layer for filling spaces between wiring lines. Repeating this process forms a multilayer wiring structure. The lower layer-side first wiring and the upper layer-side first wiring are connected to each other through a via penetrating the interlayer insulating film therebetween. The lowermost layer-side first wiring is connected to the function element (for example, a source region, a drain region or a gate electrode of the MOSFET) on the semiconductor substrate through a via within a contact hole penetrating the lowermost layer-side interlayer insulating film.

The wiring (first wiring 105) of the first wiring-structure layer 104 can be formed by regular wiring technology using a wiring material, such as copper or aluminum. The first wiring can be formed by, for example, a damascene method. Wiring formation by the damascene method can be performed in such a manner as described below. First, an insulating film is formed on a semiconductor substrate. In this insulating film, trenches shaped as a desired wiring pattern or via pattern are formed using a lithography technique and a dry etching technique. Next, a barrier metal layer is formed across the entire surface of the substrate including interior portions of these trenches by using a sputtering method, a CVD (Chemical Vapor Deposition) method, an ALD (Atomic Layer Deposition) method, or the like. In addition, a power supply layer for electrolytic plating is formed by a sputtering method or the like. Then, a copper film is formed by an electrolytic copper plating method, so as to fill the trenches. Next, the copper film is polished by a CMP (Chemical Mechanical Polishing) method, so that the barrier metal and copper remain only within the trenches. The thickness of the first wiring can be set to the range of, for example, 0.08 to 2 μm, and is preferably set to 0.1 μm or greater. On the other hand, the thickness is preferably set to 1.6 μm or less, more preferably to 1.2 μm or less. The thickness of the interlayer insulating film (not including an inter-wiring insulating film) can be set to the range of, for example 0.01 to 2 μm and is preferably set to 0.03 μm or greater. On the other hand, the thickness is preferably set to 1.6 μm or less, more preferably 1.2 μm or less.

As the material of an insulating layer (first insulating layer) of the first wiring-structure layer 104, an inorganic insulating material, among others, can be suitably used with importance attached to enhancing accuracy at the time of manufacture to cope with a reduced wiring rule or to the stability of electrical characteristics. As a low-dielectric constant material (low-k material) lower in relative permittivity than SiO₂, an organic insulating material may be used in part. Examples of the inorganic insulating material include SiO₂, Si₃N₄, NSG (non-dope silicate glass), BSG (boron silicate glass), PSG (phosphosilicate glass), and BPSG (boron phosphorous silicate glass). In the example of the present exemplary embodiment, an SiO₂ film, among others, is used as the first insulating layer 106.

In order to reduce parasitic capacitance with respect to signal-line wiring, at least one interlayer insulating film or inter-wiring insulating film, among a plurality of insulating films provided in the vicinity of the semiconductor substrate, is desirably formed of a low-k material. Examples of the low-k material include an inorganic insulating film made of a porous silicon oxide film (porous silica film), porous HSQ (hydrogen silsesquioxane) or the like, an organic insulating film made of porous MSQ (methylsilsesquioxane), organic polymer or the like, and a fluorine-containing insulating film made of fluorine-based polymer or the like. A low-k material whose elastic modulus at 25° C. is within the range of 4 to 10 GPa can be suitably used.

The second wiring-structure layer 107 of the semiconductor element 117 can be formed utilizing wiring technology suitable for a wiring size intermediate between those of a semiconductor manufacturing process and a printed-wiring substrate manufacturing process, i.e., wiring technology (wafer-level rewiring technology) known as so-called super-connect.

The second wiring 108 can be formed by a subtractive method, a semi-additive method, a full-additive method, or the like. From the viewpoint of dealing with finer pitches, the semi-additive method is preferred. The semi-additive method is a method in which after a power supply layer is formed by a nonelectrolytic plating method, a sputtering method, a CVD method or the like, resist in which openings are created into a desired pattern is formed, metal is deposited within the resist openings by an electrolytic plating method, and the resist is removed. Thereafter, the power supply layer is etched to obtain a desired wiring pattern.

As the material of the second wiring 108, it is possible to use a metal material composed of one or more than one type of material selected from the group consisting of copper, silver, gold, nickel, aluminum, titanium, molybdenum, tungsten, and palladium. In particular, copper is desirable from the viewpoint of electrical resistance values and costs.

In the example of the present exemplary embodiment, 5 μm-thick second wiring made of copper is formed by a semi-additive method. In this case, the first wiring is set to a maximum thickness of 1 μm.

The thickness of the second wiring 108 is greater than the thickness of the first wiring 105, and is preferably twice or more, more preferably three times or more the thickness thereof. Furthermore, the thickness of the second wiring 108 can be set to four times or more the thickness of the first wiring 105. Since wiring resistance becomes lower as the thickness of the second wiring becomes greater, a plurality of power supply lines and a plurality of grounding lines of the semiconductor element can be bundled respectively to reduce the number of terminals. Concurrently, it is also possible to easily lead out new signal lines, which used to be difficult to lead out from a semiconductor element, from the semiconductor element 117 to the outside, by virtue of the second wiring-structure layer 107. If the second wiring is too thick, it becomes difficult to form a desired wiring structure connected favorably to a fine (particularly narrow-pitched) first wiring-structure layer, and the thickness of the second wiring-structure layer increases significantly. Accordingly, in order to prevent the second wiring from being too thick, the thickness of the second wiring is preferably set as appropriate within the range of no greater than, for example, 10 times the maximum thickness of the first wiring. In addition, the thickness of the second wiring is preferably set less than the minimum thickness of the third wiring (or upper surface-side wiring).

As the material of the second insulating layer 109, a resin insulating material can be suitably used. For example, the second insulating layer 109 can be formed using a photosensitive or nonphotosensitive organic material. Examples of this resin insulating material include epoxy resin, epoxy acrylate resin, urethane acrylate resin, polyester resin, phenol resin, polyimide resin, BCB (benzocyclobutene) resin, PBO (polybenzoxazole) resin, and polynorbornene resin, though not limited to these.

If a photosensitive material is used as the resin insulating material, via holes can be formed by a photolithographic method. Even if a nonphotosensitive material or an organic material which is photosensitive but low in pattern resolution is used, via holes can still be formed by a laser or a dry etching method, or by means of blasting.

By using a resin material for the second insulating layer, stress on the semiconductor element arising due to strain between the semiconductor element and the third wiring-structure layer (or the upper surface-side wiring) can be relieved by the deformation of the second insulating layer. Thus, it is possible to effectively reduce stress propagation to the first wiring-structure layer. The elastic modulus of the second insulating layer at 25° C. is desirably within the range of, for example, 0.15 to 8 GPa. If the elastic modulus of the insulating material is too low, the amount of deformation in the second insulating layer at the time of stress relief is significantly large, and therefore, almost all of stress is applied to the second wiring. Consequently, disconnection in the second wiring or breakage at a boundary face between the second wiring and a via becomes liable to occur. If the elastic modulus of the insulating material is too high, the amount of deformation in the second insulating layer falls short. Consequently, stress relief by the second wiring-structure layer becomes insufficient, thus degrading the effect of suppressing interlayer peeling in the first wiring-structure layer, insulating film breakdown, or the like. In addition, by combining insulating materials so that the elastic modulus of the second insulating layer is lower than the elastic modulus of the insulating film (first insulating layer) of the first wiring-structure layer, it is possible to more effectively relieve stress in the second wiring-structure layer. Thus, the effect of protecting the first wiring-structure layer can be enhanced. If a third wiring-structure layer is provided, it is possible to attain a stress relief effect by virtue of the second wiring-structure layer, while more sufficiently securing electrical connection functions within the second wiring-structure layer, for the reason that the second wiring-structure layer includes, as the second insulating layer, an insulating layer greater in elastic modulus than the third insulating layer.

In the example of the present exemplary embodiment, a 10 μm-thick second insulating layer made of polyimide resin is formed. In this case, the first insulating layer is set to a maximum thickness of 2 μm.

The thickness of the second insulating layer 109 is set greater than the thickness of the first insulating layer 106. The thickness of the second insulating layer 109 is preferably twice or more, more preferably three times or more the thickness of the first insulating layer 106. Furthermore, the thickness of the second insulating layer 109 can be set to a thickness four times or more the thickness of the first insulating layer 106. More sufficient coatability, impact resistance, and stress relief effect can be obtained with an increase in the thickness of the second insulating layer. If the second insulating layer is too thick, however, it is difficult to form vias, and the size of the wiring substrate in the thickness direction thereof becomes larger. Accordingly, in order to prevent the second insulating layer from being too thick, the thickness of the second insulating layer is preferably set as appropriate, within the range of not greater than, for example, 20 times the maximum thickness of the first insulating layer. If a third wiring-structure layer is provided, the thickness of the second insulating layer is preferably set less than the minimum thickness of the third insulating layer.

The second insulating layer 109 can be formed using, for example, a transfer molding method, a compressed formation molding method, a printing method, a vacuum pressing method, a vacuum laminating method, a spin coating method, a die coating method, a curtain coating method, or a photolithographic method. In the example of the present exemplary embodiment, the second insulating layer is formed by a spin coating method.

In the formation of the second wiring-structure layer, use of a composite material that is made by impregnating a reinforcing material, such as woven cloth or nonwoven cloth made of glass cloth, aramid fiber or the like, with a resin, or use of a resin composition that contains an inorganic filler or an organic filler, as the material of the second insulating layer 109, makes short-circuiting or the like between wirings more liable to occur as wiring becomes finer. For this reason, a material not containing any reinforcing material or filler is preferred as the material of the second insulating layer.

The third wiring-structure layer 110 can be formed by using a regular printed-wiring substrate manufacturing technique. In particular, the third wiring-structure layer 110 can be suitably formed using a build-up method to be applied to the formation of an interposer board.

The third wiring 111 or the upper surface-side wiring can be formed by a subtractive method, a semi-additive method, a full-additive method, or the like. The subtractive method is a method in which resist of a desired pattern is formed on copper foil provided on a substrate or an insulating layer. After unnecessary copper foil is etched away, resist is separated off to obtain the desired pattern. The semi-additive method is a method in which after a power supply layer is formed by a nonelectrolytic plating method, a sputtering method, a CVD method, or the like, resist in which openings are created into a desired pattern is formed, metal is deposited within the resist openings by an electrolytic plating method, and the resist is removed. Thereafter, the power supply layer is etched to obtain a desired wiring pattern. The full-additive method is a method in which after a nonelectrolytic plating catalyst is adsorbed onto a substrate or an insulating layer, resist of a desired pattern is formed. The catalyst is activated with this resist left as an insulating film. Metal is deposited in openings of the resist insulating film by a nonelectrolytic plating method to obtain a desired wiring pattern.

As the material of the third wiring 111 or the upper surface-side wiring, it is possible to use a metal material composed of one or more than one type of material selected from the group consisting of copper, silver, gold, nickel, aluminum, titanium, molybdenum, tungsten, and palladium. In particular, copper is desirable from the viewpoint of electrical resistance values and costs.

In the example of the present exemplary embodiment, approximately 10 μm-thick third wiring made of copper is formed by a semi-additive method.

The thickness of the third wiring or upper surface-side wiring is greater than the thickness of the second wiring 108, and is preferably 1.5 times or more, more preferably twice or more the thickness of the second wiring 108. Since wiring resistance becomes lower as the wiring becomes thicker, power supply lines and grounding lines led out from the semiconductor element can be bundled respectively to reduce the number of terminals. If the wiring is too thick, however, it becomes difficult to form a desired wiring structure connected favorably to a relatively fine (particularly relatively narrow-pitched) second wiring-structure layer, and the thickness of the third wiring-structure layer increases significantly. Accordingly, in order to prevent the third wiring or the upper surface-side wiring from being too thick, the thickness of the third wiring or the upper surface-side wiring is preferably set as appropriate, within the range of no greater than, for example, 10 times the maximum thickness of the second wiring.

As the material of the third insulating layer 112, a resin insulating material can be suitably used. For example, the third insulating layer 112 can be formed using a photosensitive or nonphotosensitive organic material. Examples of this resin insulating material include epoxy resin, epoxy acrylate resin, urethane acrylate resin, polyester resin, phenol resin, polyimide resin, BCB (benzocyclobutene) resin, PBO (polybenzoxazole) resin, and polynorbornene resin. Examples of this resin insulating material also include a composite material that is made by impregnating a reinforcing material, such as woven or nonwoven cloth made of glass cloth, aramid fiber or the like, with any of those resins mentioned above, a resin composition that contains any one of the above-mentioned resins and an inorganic or organic filler, as well as silicon resin (silicone resin).

In the example of the present exemplary embodiment, filler-containing epoxy resin advantageous to the formation of irregularities, for example, is used as the material of the third insulating layer, from the viewpoint of forming a sufficient amount of irregularity on the surface of the third insulating layer to enhance adhesion to the 10 μm-thick third wiring 111. The thickness of the third insulating layer made of this material is set to, for example, 20 μm, i.e., twice the thickness of the second insulating layer 109 set to 10 μm.

The thickness of a third insulating layer 112 is set greater than the thickness of the second insulating layer 109, and is preferably 1.5 times or more, more preferably twice or more the thickness of the second insulating layer 109. More sufficient coatability, impact resistance, and stress relief effect can be obtained with an increase in the thickness of the third insulating layer. If the third insulating layer is too thick, however, it is difficult to form vias, and the size of the wiring substrate in the thickness direction thereof becomes larger. Accordingly, in order to prevent the third insulating layer from being too thick, the thickness of the third insulating layer is preferably set as appropriate, within the range of not greater than, for example, 10 times the maximum thickness of the second insulating layer.

The third insulating layer 112 can be formed using, for example, a transfer molding method, a compressed formation molding method, a printing method, a vacuum pressing method, a vacuum laminating method, a spin coating method, a die coating method, a curtain coating method, or a photolithographic method. In the example of the present exemplary embodiment, the third insulating layer is formed by a vacuum laminating method.

The peripheral insulating layer 113 is preferably superior in adhesion to side surfaces (or side surfaces and an upper surface) of the semiconductor element 117, easy to form at relatively low temperatures, and less likely to cause the warpage of the wiring substrate as a whole. The peripheral insulating layer 113 is preferably made of a resin material and can be formed using, for example, a photosensitive or nonphotosensitive organic material. Examples of this resin material include epoxy resin, epoxy acrylate resin, urethane acrylate resin, polyester resin, phenol resin, polyimide resin, BCB (benzocyclobutene), PBO (polybenzoxazole), and polynorbornene resin. Examples of this resin insulating material also include a composite material that is made by impregnating a reinforcing material, such as woven or nonwoven cloth made of glass cloth, aramid fiber or the like, with any of those resins mentioned above, a resin composition that contains any one of the above-mentioned resins and an inorganic or organic filler, as well as silicon resin (silicone resin). In the example of the present exemplary embodiment, epoxy resin is used.

The peripheral insulating layer 113 can be formed by providing an insulating layer made of such a resin material as described above on the supporting substrate 101 by a vacuum laminating method, a vacuum pressing method, or the like, so as to cover the semiconductor element 117. The peripheral insulating layer may be formed of a single resin layer or of a laminated body including a plurality of resin layers. If the peripheral insulating layer is formed of the laminated body, the peripheral insulating layer may be formed by going through a plurality of steps separately. In cases where a resin layer that contains a reinforcing material made of glass cloth, aramid fiber or the like is provided, an opening capable of accommodating a semiconductor element is formed in this resin layer. Thus, the peripheral insulating layer can be formed using the resin layer having such an opening.

A connection between the second wiring of the second wiring-structure layer 107 and the lowermost layer-side third wiring of the third wiring-structure layer 110 (or the upper surface-side wiring) can be made in such a manner as described below:

After forming the peripheral insulating layer 113 for covering the second wiring-structure layer 107, an opening is formed in the insulating layer (peripheral insulating layer 113) immediately above the second wiring-structure layer by using a laser or the like, so that a terminal portion of the uppermost layer-side second wiring or a terminal, such as a pad, to be connected to the second wiring becomes exposed. A conductive material is filled in this opening to form a via. Then, third wiring (or upper surface-side wiring) is formed so as to connect to this via.

As an alternative, a bump (also referred to as a “post”) is previously formed on the terminal portion of the uppermost layer-side second wiring or the terminal, such as a pad, to be connected to the second wiring. A semiconductor element in which such a bump is formed is fixed to a supporting substrate. Next, the peripheral insulating layer 113 is formed, and a portion of the insulating layer (peripheral insulating layer 113) on the bump is removed to expose an upper surface of the bump. Then, third wiring (fan-out wiring) is formed so as to connect to this bump.

Note that terminal portions of the uppermost layer-side second wiring of the second wiring-structure layer or terminals, such as pads, to be connected to the second wiring may include terminals to be connected to the upper layer-side third wiring through vias, in addition to terminals to be connected to the lowermost layer-side third wiring (fan-out wiring) of the third wiring-structure layer.

The wiring pitches of the wiring substrate of the present exemplary embodiment can be expanded in the order from the first wiring-structure layer 104, the second wiring-structure layer 107, and the third wiring-structure layer 110. In the second wiring-structure layer 107, power-line wiring and ground-line wiring can respectively be consolidated. In addition, a wiring structure (or the third wiring-structure layer) and terminals can be formed in an upper layer side, with pitches fully expanded with respect to pitches within the semiconductor element by virtue of fan-out wiring led out from the second wiring-structure layer. As a result, it is possible to enhance reliability and form a wiring substrate (semiconductor package) containing a high-density semiconductor element (for example, an LSI chip).

In addition, for the second wiring-structure layer 107, a resin insulating film not containing a filler can be used as the second insulating layer 109. Accordingly, it is possible to fully cope with fine wiring pitches of the lower layer-side wiring structure (first wiring-structure layer 104). Thus, a highly reliable wiring structure can be formed.

Furthermore, for the third wiring-structure layer 110, a material lower in curing temperature than the second insulating layer can be used as the third insulating layer 112. Consequently, it is possible to realize a low degree of warpage even when the wiring substrate as a whole is made thinner.

If as an example of the present exemplary embodiment, polyimide resin not containing a filler is used in the second insulating layer and filler-containing epoxy resin low in curing temperature is used in the third insulating layer, process temperature can be made lower, and therefore, the amount of warpage can be reduced, compared with a case in which epoxy resin is used on the lower layer side and polyimide resin high in curing temperature is used on the upper layer side. In addition, a second wiring-structure layer adapted to the fine wiring structure of the first wiring-structure layer can be formed since the second insulating layer does not contain any filler. Furthermore, since the third insulating layer contains a filler, it is possible to enhance the heat resistance and mechanical strength of not only the third wiring-structure layer but also the wiring substrate as a whole.

A temperature cycling test (one cycle: durations of 10 min at −55° C. and 10 min at +125° C.) of the wiring substrate of an example of the present exemplary embodiment showed that it is possible to prevent open-circuit failure from occurring in the wiring substrate up to a 3000th cycle, whereas a wiring substrate (not provided with a second wiring-structure layer) based on the related art suffered open-circuit failure at a point near a 1000th cycle.

### Modified Example of First Exemplary Embodiment

FIG. 3 is a cross-sectional view illustrating a modified example of the wiring substrate according to the first exemplary embodiment of the present invention.

In this example, the peripheral insulating layer 113 is not provided on an upper surface of the semiconductor element 117, but has contact only with a lateral periphery thereof. Thus, the modified example is the same as the above-described first exemplary embodiment, except that the modified example differs therefrom in the terminal structure of the semiconductor element. According to such a structure as described above, a terminal that connects to the second wiring 108 of the second wiring-structure layer 107 can be connected to the third wiring 111 of the third wiring-structure layer 110 without having to provide a via on the element. Consequently, narrow-pitch connection between the second wiring-structure layer 107 and the third wiring-structure layer 110 becomes possible. Thus, a greater number of signal lines can be led out from the semiconductor element 117.

### Second Exemplary Embodiment

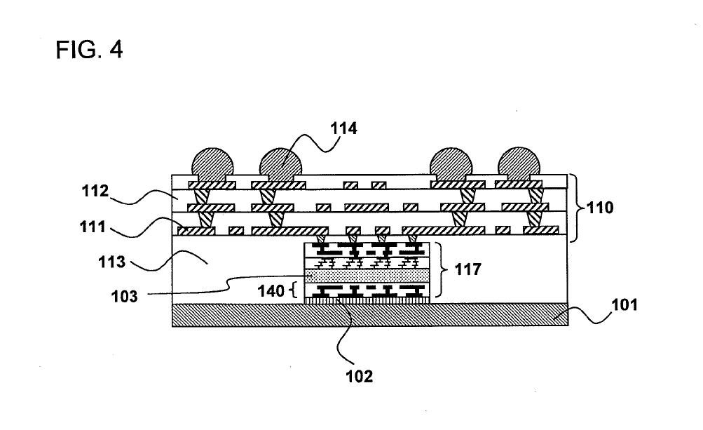

FIG. 4 is a cross-sectional view illustrating a wiring substrate according to a second exemplary embodiment of the present invention.

The present exemplary embodiment is the same as the first exemplary embodiment, except that a wiring-structure layer (hereinafter referred to as the “fourth wiring-structure layer”) 140 similar to the second wiring-structure layer 107 is also formed on the rear surface side of a semiconductor substrate 103. The wiring pattern of the fourth wiring-structure layer 140 need not be the same as the wiring pattern of the second wiring-structure layer 107. In addition, the number of layers of the fourth wiring-structure layer 140 may be set arbitrarily. The peripheral insulating layer 113 surrounds the outer circumferential side surface of the fourth wiring-structure layer 140, as well as the outer circumferential side surfaces of the first wiring-structure layer 104 and second wiring-structure layer 107.

The fourth wiring-structure layer can be provided on a thinly-ground rear surface of the semiconductor substrate 103. A semiconductor element including the fourth wiring-structure layer 140 is provided with an adhesion layer 102 on the lower surface thereof, and is fixed onto a supporting substrate 101.

According to such a structure as described above, the impact resistance of the semiconductor element is enhanced, compared with a thinly-ground semiconductor element 117 alone, since an insulating layer made of highly tough resin is provided on both sides of the semiconductor element. In addition, effects by insulating layers on both sides are cancelled out to enable reduction in warpage. Consequently, process windows, such as pick-up conditions (rate and amount of plunge-up), conditions of suction by a head, and mounting conditions (pressurization and heating) at the time of mounting are widened. These widened process windows not only stabilize manufacturing processes, but also improve suction properties and image recognition properties by virtue of the semiconductor element being planar. Accordingly, it is possible to improve mounting accuracy at the time of mounting the semiconductor element onto the supporting substrate 101. As a result, it is possible to reduce warpage of the wiring substrate and improve the yield thereof.

Note that in the structure illustrated in FIG. 4, the peripheral insulating layer 113 is also present on the upper surface of the semiconductor element 117, and terminals of the element and the third wiring are connected though vias. Alternatively, as in the above-described example illustrated in FIG. 3, the peripheral insulating layer may be provided only in the lateral periphery of the semiconductor element and terminals of the element and the third wiring may be connected without providing any vias.

### Modified Example of Second Exemplary Embodiment

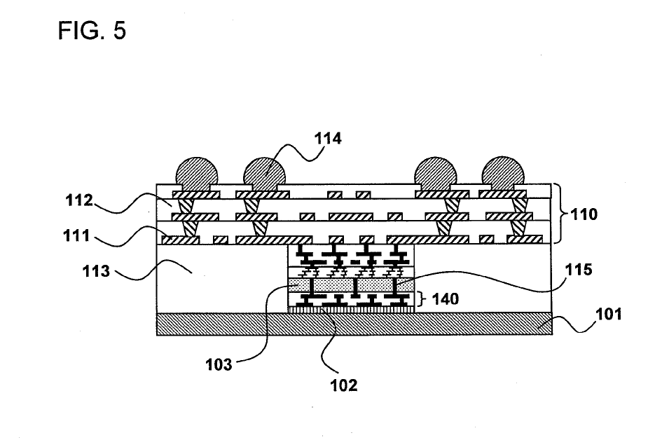

FIG. 5 is a cross-sectional view illustrating a modified example of the second exemplary embodiment of the present invention.

This example is the same as the above-described first exemplary embodiment, except that a feed-through via (hereinafter referred to as the “intra-element through-substrate via”) 115 is formed in the semiconductor substrate 103.

The position, size and quantity of the intra-element through-substrate via 115 can be set arbitrarily. The material of the via may be either an electrical conductor or an insulator. As the intra-element through-substrate via 115, a via made of metal that includes copper is preferred.

According to such a structure as described above, the intra-element through-substrate via functions as a reinforcing via. In addition, since an insulating layer made of highly tough resin is provided on both sides of the semiconductor element, not only is impact resistance of the semiconductor element enhanced compared with the thinly-ground semiconductor element 117, but also effects by insulating layers on both sides are cancelled out to enable reduction in warpage. Consequently, process windows, such as pick-up conditions (rate and amount of plunge-up), conditions of suction by a head, and mounting conditions (pressurization and heating) at the time of mounting are widened. These widened process windows not only stabilize manufacturing processes, but also improve suction properties and image recognition properties by virtue of the semiconductor element being planar. Accordingly, it is possible to improve mounting accuracy at the time of mounting the semiconductor element onto the supporting substrate 101. As a result, it is possible to reduce warpage of the wiring substrate and improve the yield thereof. In addition, by electrically connecting the first and the fourth wiring through the intra-element through-substrate via 115, it is possible to route signal wiring, power supply wiring, and grounding wiring also on the rear surface side of the semiconductor element. Thus, it becomes possible to build in a more highly-functional semiconductor element.

Note that in the structure illustrated in FIG. 5, the peripheral insulating layer 113 is present only in the lateral periphery of the semiconductor element 117, and terminals of the element and the third wiring are connected without providing any vias. Alternatively, as in the above-described example illustrated in FIG. 4, the peripheral insulating layer may be present on the upper surface of the semiconductor element 117 and terminals of the element and the third wiring may be connected through vias.

### Third Exemplary Embodiment

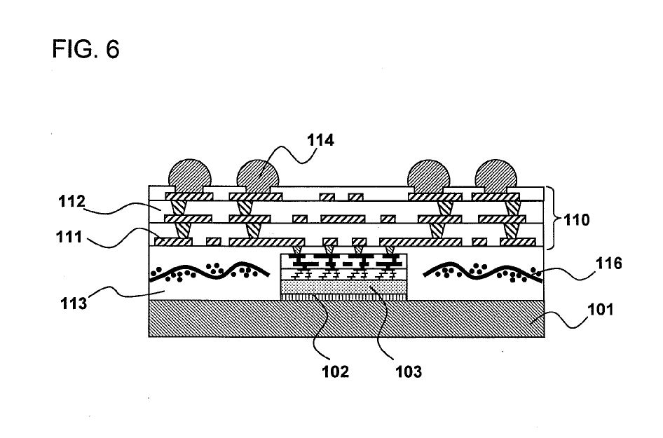

FIG. 6 is a cross-sectional view illustrating a wiring substrate according to a third exemplary embodiment of the present invention.

The present exemplary embodiment is the same as the above-described first exemplary embodiment, except that the peripheral insulating layer 113 includes a reinforcing material 116 made of glass cloth.

According to such a structure as described above, it is possible to reduce the warpage of the wiring substrate as a whole. Here, the reinforcing material 116 is not limited to glass cloth, but may be nonwoven cloth, such as aramid nonwoven cloth, or thin metal foil.

Note that in the structure illustrated in FIG. 6, the peripheral insulating layer 113 is also present on the upper surface of the semiconductor element 117, and terminals of the element and the third wiring are connected though vias. Alternatively, as in the above-described example illustrated in FIG. 3, the peripheral insulating layer may be provided only in the lateral periphery of the semiconductor element and terminals of the element and the third wiring may be connected without providing any vias.

### Fourth Exemplary Embodiment

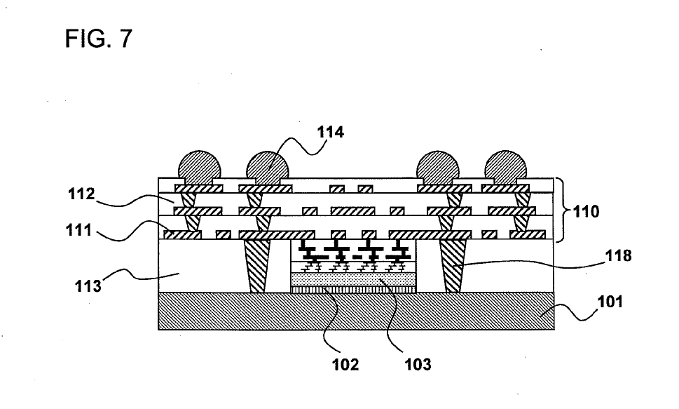

FIG. 7 is a cross-sectional view illustrating a wiring substrate according to a fourth exemplary embodiment of the present invention.

In the present exemplary embodiment, an element-side via 118 that penetrates the peripheral insulating layer 113 is provided and, through this element-side via, the lowermost layer-side third wiring 111 can be connected to the supporting substrate 101.

According to such a structure as described above, a circuit potential can be provided if the supporting substrate is a conductor. By fixing the supporting substrate at, for example, a ground potential, it is possible to reduce electromagnetic radiation noise for the wiring substrate as a whole. In addition, it is possible to raise breakdown voltage with extraneous high-voltage pulses.

Note that in the structure illustrated in FIG. 7, the peripheral insulating layer 113 is present only in the lateral periphery of the semiconductor element 117, and terminals of the element and the third wiring are connected without providing any vias. Alternatively, as in the above-described example illustrated in FIG. 1, the peripheral insulating layer may be present on the upper surface of the semiconductor element 117 and terminals of the element and the third wiring may be connected through vias.

In the wiring substrates described heretofore, an LCR element serving as a circuit noise filter may be provided within any one of the wiring-structure layers. Preferred in particular as a dielectric material for composing a capacitor is a metal oxide, such as titanium oxide, tantalum oxide, Al₂O₃, SiO₂, ZrO₂, HfO₂, and Nb₂O₅; perovskite-based materials (0≦x≦1, 0≦y≦1), such as BST ((Baₓ, Sr₁₋ₓ)TiO₃), PZT (Pb (Zrₓ, Ti₁₋ₓ)O₃, and PLZT ((Pb_{1-y}, La_{y})(Zrₓ, Ti₁₋ₓ)O₃); and a Bi-based layer-like compound, such as SrBi₂Ta₂O₉. In addition, as a dielectric material for composing a capacitor, an organic material mixed with an inorganic material or a magnetic material, or the like may be used.

Furthermore, a wiring substrate according to an exemplary embodiment of the present invention may include a plurality of semiconductor elements. In addition to a semiconductor element, a wiring substrate according to an exemplary embodiment of the present invention may contain, as a passive component, an LCR part, an MEMS part, a sensor, an energy device, an optical part, and the like.

An exemplary advantage according to the invention is that it is possible to provide a thin, high-reliability wiring substrate containing a high-density semiconductor element.

While the invention has been particularly shown and described with reference to exemplary embodiments thereof, the invention is not limited to these exemplary embodiments. It will be understood by those of ordinary skill in the art that various changes in form and details may be made therein without departing from the spirit and scope of the present invention as defined by the claims.

What is claimed is:

1. A wiring substrate containing a semiconductor element, the wiring substrate comprising:
a supporting substrate;
a semiconductor element provided on the supporting substrate;
a peripheral insulating layer provided on the supporting substrate and covering at least an outer circumferential side surface of the semiconductor element; and
upper surface-side wiring provided on the upper surface side of the wiring substrate,
the semiconductor element comprising:
a semiconductor substrate;
a first wiring-structure layer comprising first wiring and a first insulating layer alternately formed on the semiconductor substrate; and
a second wiring-structure layer comprising second wiring and a second insulating layer alternately formed on the first wiring-structure layer,
wherein the upper surface-side wiring comprises fan-out wiring led out from immediately above the semiconductor element to a peripheral region external to an outer edge of the semiconductor element, the fan-out wiring being electrically connected to the first wiring through the second wiring;
the thickness of the second wiring is greater than the thickness of the first wiring but less than the thickness of the upper surface-side wiring; and
the second insulating layer is formed of a resin material and greater in thickness than the first insulating layer.

2. The wiring substrate according to claim 1, wherein the supporting substrate is a metal plate.

3. The wiring substrate according to claim 1, wherein the second insulating layer is composed of a resin material without filler.

4. The wiring substrate according to claim 1, wherein the first wiring-structure layer includes, as the first insulating layer, an insulating layer composed of an inorganic insulating material.

5. The wiring substrate according to claim 1, wherein the first wiring-structure layer includes, as the first insulating layer, an insulating layer composed of a low-dielectric constant insulating material.

6. The wiring substrate according to claim 1, wherein the second wiring-structure layer includes, as the second insulating layer, an insulating layer having an elastic modulus lower than the elastic modulus of the first insulating layer.

7. The wiring substrate according to claim 1, wherein the second wiring has a thickness twice or more the thickness of the first wiring.

8. The wiring substrate according to claim 1, wherein the second insulating layer has a thickness twice or more the thickness of the first insulating layer.

9. The wiring substrate according to claim 1, wherein the second wiring is formed by a design rule different from the design rule of the first wiring and the design rule of the upper surface-side wiring, and the minimum wiring width and the minimum wiring pitch of the second wiring are greater than the minimum wiring width and the minimum wiring pitch of the first wiring, respectively, but less than the minimum wiring width and the minimum wiring pitch of the upper surface-side wiring.

10. The wiring substrate according to claim 1, wherein the first wiring-structure layer further includes, on the upper surface side thereof, a first connecting part connected to the second wiring, the second wiring-structure layer further includes, on the upper surface side thereof, a second connecting part conductive to the first connecting part and connected to the fan-out wiring, and the second connecting part is repositioned in a direction farther from a position of the first connecting part toward an outer edge side of the semiconductor element.

11. The wiring substrate according to claim 1, further comprising a protective insulating film covering the upper surface-side wiring,
wherein the protective insulating film includes an opening such that the wiring substrate is provided with an external terminal composed of an exposed portion of the upper surface-side wiring within the opening or of a conductive part provided in the opening.

12. The wiring substrate according to claim 1, further comprising a third wiring-structure layer including third wiring and a third insulating layer alternately formed on the semiconductor substrate, wherein the third wiring-structure layer includes the fan-out wiring as the third wiring on at least the lowermost layer side, and the fan-out wiring is electrically connected to an upper layer-side wiring provided in the third wiring-structure layer as the third wiring.

13. The wiring substrate according to claim 12, wherein the second insulating layer is composed of a resin material without filler, and the third wiring-structure layer includes, as the third insulating layer, an insulating layer composed of a filler-containing resin material.

14. The wiring substrate according to claim 12, wherein the thickness of the third wiring is greater than the thickness of the second wiring, and the thickness of the third insulating layer is greater than the thickness of the second insulating layer.

15. The wiring substrate according to claim 14, wherein the third wiring has a thickness twice or more the thickness of the second wiring.

16. The wiring substrate according to claim 14, wherein the third insulating layer has a thickness twice or more the thickness of the second insulating layer.

17. The wiring substrate according to claim 12, wherein the second wiring-structure layer includes as the second insulating layer an insulating layer having an elastic modulus higher than the elastic modulus of the third insulating layer.

18. The wiring substrate according to claim 12, further comprising an insulating layer on the uppermost layer side,
wherein the insulating layer includes an opening such that the wiring substrate is provided with an external terminal composed of an exposed portion of the third wiring within the opening or of a conductive part provided in the opening.

19. The wiring substrate according to claim 1, wherein the peripheral insulating layer includes a filler.

20. The wiring substrate according to claim 1, wherein the peripheral insulating layer contains a reinforcing material made of woven or nonwoven cloth.

21. The wiring substrate according to claim 1, wherein the peripheral insulating layer covers the outer circumferential side surface of the semiconductor element without covering the upper surface thereof, and the fan-out wiring is connected to a terminal on an upper surface of the semiconductor element.

22. The wiring substrate according to claim 1, wherein the peripheral insulating layer covers an upper surface and the outer circumferential side surface of the semiconductor element, and the fan-out wiring is provided on the peripheral insulating layer.

23. The wiring substrate according to claim 1, further comprising an element-side via penetrating the peripheral insulating layer, wherein the element-side via connects the third wiring and the supporting substrate.

24. The wiring substrate according to claim 1, wherein the semiconductor element further comprises, on the lower surface side of the semiconductor substrate, a fourth wiring-structure layer including a fourth insulating layer and fourth wiring.

25. The wiring substrate according to claim 24, wherein the semiconductor element further comprises an intra-element via penetrating the semiconductor substrate, and the intra-element via electrically connects the first wiring and the fourth wiring.

26. The wiring substrate according to claim 1, wherein the semiconductor element further comprises a reinforcing via penetrating the semiconductor substrate.
